(19) United States
(12) Patent Application Publication
(10) Pub. No.: US 2017/0140976 A1
(43) Pub. Date: May 18, 2017

(54) HEAT TREATMENT APPARATUS FOR HEATING SUBSTRATE BY IRRADIATION WITH FLASH LIGHT

(71) Applicant: SCREEN Holdings Co., Ltd., Kyoto (JP)

(72) Inventors: Makoto ABE, Kyoto-shi (JP); Takahiro YAMADA, Kyoto-shi (JP); Kazuhiko FUSE, Kyoto-shi (JP)

(21) Appl. No.: 15/417,463

(22) Filed: Jan. 27, 2017

Related U.S. Application Data
(63) Continuation of application No. 14/104,178, filed on Dec. 12, 2013.

(30) Foreign Application Priority Data
Dec. 13, 2012 (JP) 2012-272002

(51) Int. Cl. H01L 21/687; H01L 21/67; H05B 3/00; H01L 21/324

(52) U.S. Cl. CPC H01L 21/68735; H01L 21/324; H01L 21/67115; H05B 3/0047

(57) ABSTRACT

A susceptor of a holding part for holding a semiconductor wafer includes a disc-shaped holding plate, an annular shaped guide ring, and a plurality of support pins. The guide ring has an inside diameter greater than the diameter of the semiconductor wafer and is installed on the peripheral portion of the top face of the holding plate. The guide ring has a tapered surface along the inner circumference. The semiconductor wafer before irradiated with flash light is supported by the support pins. The annular shape of the guide ring increases the contact area when the semiconductor wafer that has jumped off the susceptor and fallen when irradiated with flash light collides with the guide ring, thus reducing the impact of the collision and preventing cracks in the substrate.

### CROSS-REFERENCE TO RELATED APPLICATIONS

This application is a continuation of U.S. patent application Ser. No. 14/104,178, filed Dec. 12, 2013, which claims the benefit of Japanese Patent Application No. 2012-272002, filed Dec. 13, 2012, incorporated herein by reference.

### BACKGROUND OF THE INVENTION

Field of the Invention

The present invention relates to a heat treatment apparatus for heating a sheet precision electronic substrate (hereinafter, simply referred to as a “substrate”) such as a disc-shaped semiconductor wafer by applying flash light to the substrate.

Description of the Background Art

In the manufacturing process of a semiconductor device, the introduction of impurities is an essential step for forming pn junctions in a semiconductor wafer. Currently, it is common to use ion implantation and subsequent annealing to introduce impurities. Ion implantation is a technique by which impurity elements such as boron (B), arsenic (As), and phosphorus (P) are ionized and caused to collide with a semiconductor wafer at a high acceleration voltage to physically implant impurities. The implanted impurities are activated by annealing treatment. If, at this time, the annealing time is about several seconds or more, the implanted impurities will be diffused deeply by heat, which may result in too deeper a junction depth and a possible impediment to the formation of a favorable device.

For this reason, attention is now placed on flash-lamp annealing (FLA) as an annealing technique for heating a semiconductor wafer in an extremely short time. Flash-lamp annealing is a heat treatment technique for raising the temperature of only the surface of a semiconductor wafer implanted with impurities in an extremely short time (several milliseconds or less) by irradiating the surface of the semiconductor wafer with flash light using xenon flash lamps (the term “flash lamps” used hereinafter means xenon flash lamps).

The xenon flash lamps have a spectral distribution of radiation ranging from ultraviolet to near-infrared regions. The wavelength of light emitted from the xenon flash lamps is shorter than that of light emitted from conventional halogen lamps and substantially coincides with the fundamental absorption band of a silicon semiconductor wafer. Thus, it is possible, when flash light is applied from the xenon flash lamps to the semiconductor wafer, to rapidly raise the temperature of the semiconductor wafer, with a small amount of light transmitted through the semiconductor wafer. It has been found that the application of flash light in an extremely short time of several milliseconds or less makes it possible to selectively raise the temperature only near the surface of the semiconductor wafer. Accordingly, such a temperature rise in an extremely short time using the xenon flash lamps allows impurities to be only activated without being deeply diffused.

As a heat treatment apparatus using such xenon flash lamps, U. S. Patent Application Publication No. 2004/0105670 discloses an apparatus for heating a semiconductor wafer held by a quartz susceptor having a recessed portion by applying flash light to the surface of the semiconductor wafer from flash lamps. With the apparatus disclosed in U. S. Patent Application Publication No. 2004/0105670, however, the semiconductor wafer is held such that its back face is in direct contact with the placement surface of the susceptor. Thus, the temperature distribution in the wafer surface tends to be nonuniform at the time of performing preheating before the application of flash light.

On the other hand, U. S. Patent Application Publication No. 2009/0175605 discloses a technique by which a plurality of bumps (support pins) are formed on the top face of a flat plate-like susceptor, and flash light is applied to the surface of a semiconductor wafer supported by these bumps in point contact. Doing so prevents the back face of the semiconductor wafer from coming into direct contact with the top face of the susceptor, making it possible to inhibit non-uniform temperature distribution in the surface of the semiconductor wafer at the stage of preheating.

The heat treatment apparatus using flash lamps, however, instantaneously applies flash light having extremely high energy to the surface of a semiconductor wafer. Thus, the surface temperature of the semiconductor wafer rapidly increases in a moment and causes abrupt thermal expansion in the wafer surface, resulting in warping deformation of the semiconductor wafer. At this time, if a gap is formed by the support pins between the back face of semiconductor wafer and the top face of the susceptor, there is the possibility that the semiconductor wafer may jump off the susceptor due to abrupt deformation caused by thermal expansion.

In the heat treatment apparatus disclosed in U. S. Patent Application Publication No. 2009/0175605, guide pins are provided outward of the bumps on the top face of the susceptor in order to prevent positional shift of the semiconductor wafer. However, even if the guide pines are provided, the semiconductor wafer or the guide pins may be damaged as a result of the semiconductor wafer colliding with the guide pins when it has jumped and fell when irradiated with flash light. Even if no crack has occurred, there may also be a problem of a significant positional shift caused by the semiconductor wafer riding on the guide pins when it jumps and falls.

### SUMMARY OF THE INVENTION

The present invention is directed to a heat treatment apparatus for heating a disc-shaped substrate by applying flash light to the substrate.

According to one aspect of the present invention, the heat treatment apparatus includes a chamber for accommodating the substrate, a susceptor for placing and holding the substrate thereon within the chamber, the susceptor including a plate having a placement surface on which the substrate is placed, an annular shaped guide ring installed on the plate and having an inside diameter greater than a diameter of the substrate, and a plurality of support pins provided upright on the plate inward of the guide ring and for supporting the substrate in point contact with the substrate and a flash lamp for applying flash light to the substrate held by the susceptor.

By providing a large contact area when the substrate irradiated with flash light jumps off the susceptor and falls and collides with the guide ring, it is possible to reduce the impact of the collision and to prevent cracks in the substrate.

Preferably, the guide ring has a tapered surface along an inner circumference, the tapered surface tapering from above down to the plate.

When the fallen substrate collides with the tapered surface, it is possible to further reduce the impact of the collision and to more reliably prevent cracks in the substrate. In addition, the fallen substrate slides down along the tapered surface. This makes it possible to correct the position of the substrate after irradiated with flash light.

Preferably, the tapered surface has a gradient of greater than or equal to 30 degrees and less than or equal to 70 degrees to the placement surface of the plate.

When the fallen substrate collides with the tapered surface, it is possible to reduce the impact of the collision as well as to correct the position of the substrate.

Preferably, the tapered surface has an average surface roughness of less than or equal to 1.6 μm.

When the fallen substrate collides with the tapered surface, the substrate can smoothly slide along the tapered surface.

Thus, it is an object of the present invention to prevent cracks in the substrate when irradiated with flash light.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a longitudinal cross-sectional view showing a configuration of a heat treatment apparatus according to the present invention.

FIG. 2 is a perspective view showing an overall external view of a holding part.

FIG. 3 is a plan view of a susceptor of the holding part as viewed from above.

FIG. 4 is a side view of the holding part as viewed from one side.

FIG. 5 is an enlarged view of a portion where a guide ring is installed.

FIG. 6 is a plan view of a transfer mechanism.

FIG. 7 is a side view of the transfer mechanism.

FIG. 8 is a plan view showing the arrangement of a plurality of halogen lamps.

FIG. 9 shows a state in which a semiconductor wafer is held by the susceptor.

FIG. 10 shows a state in which the semiconductor wafer has jumped off the susceptor.

FIG. 11 shows a state in which the semiconductor wafer has fallen and collided with a tapered surface.

FIG. 12 shows a state in which the fallen semiconductor wafer is supported by a plurality of support pins.

### DESCRIPTION OF THE PREFERRED EMBODIMENTS

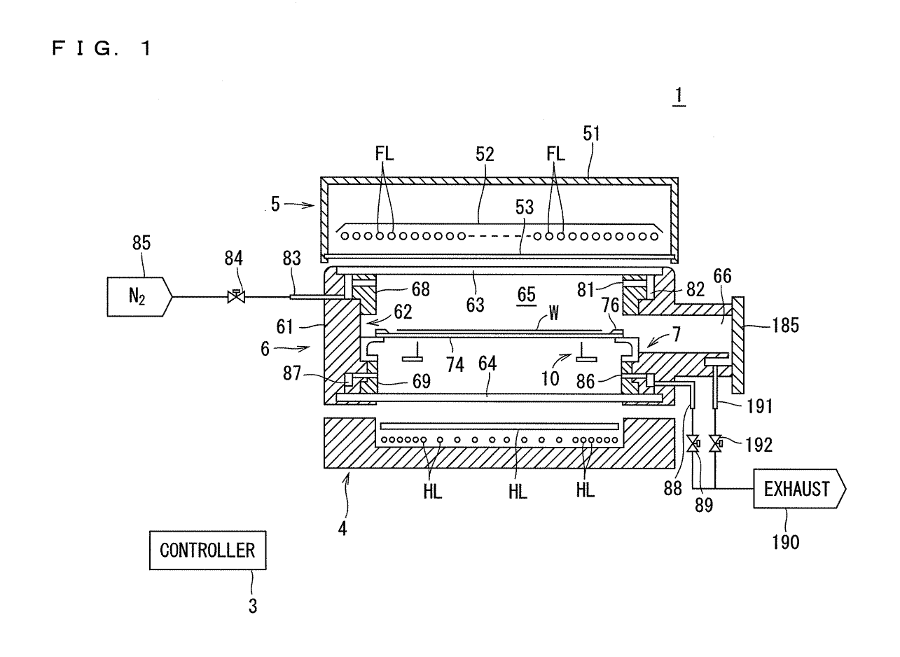

FIG. 1 is a longitudinal cross-sectional view showing a configuration of a heat treatment apparatus 1 according to the present invention. The heat treatment apparatus 1 of the present embodiment is a flash-lamp annealing apparatus for heating a disc-shaped semiconductor wafer W serving as a substrate by applying flash light to the semiconductor wafer W. Although there is no particular limitation on the size of the semiconductor wafer W to be treated, the semiconductor wafer W may have a diameter of 300 mm or 450 mm, for example. The semiconductor wafer W is implanted with impurities before being transported into the heat treatment apparatus 1, and treatment for activating the implanted impurities is performed through heat treatment by the heat treatment apparatus 1. To facilitate the understanding, the size and number of each part are exaggerated or simplified as necessary in FIG. 1 and subsequent drawings.

The heat treatment apparatus 1 includes a chamber 6 for accommodating the semiconductor wafer W, a flash heating part 5 including a plurality of flash lamps FL, and a halogen heating part 4 including a plurality of halogen lamps HL. The flash heating part 5 is provided above the chamber 6, and the halogen heating part 4 is provided below the chamber 6. The heat treatment apparatus 1 also includes, within the chamber 6, a holding part 7 for holding the semiconductor wafer W thereon in the horizontal position and a transfer mechanism 10 for transferring the semiconductor wafer W between the holding part 7 and the outside of the heat treatment apparatus 1. The heat treatment apparatus 1 further includes a controller 3 for controlling operating mechanisms provided in the halogen heating part 4, the flash heating part 5, and the chamber 6 to perform heat treatment of the semiconductor wafer W.

The chamber 6 is configured by a tubular chamber side portion 61 and quartz chamber windows attached to the upper and lower sides of the chamber side portion 61. The chamber side portion 61 has a substantially tubular shape that is open at the top and the bottom, with the opening at the top equipped with and closed by an upper chamber window 63 and the opening at the bottom equipped with and closed by a lower chamber window 64. The upper chamber window 63 constituting the ceiling portion of the chamber 6 is a disc-shaped member made of quartz and functions as a quartz window through which flash light emitted from the flash heating part 5 is transmitted into the chamber 6. The lower chamber window 64, which constitutes the floor portion of the chamber 6, is also a disc-shaped member made of quartz and functions as a quartz window that allows transmission of light emitted from the halogen heating part 4 therethrough into the chamber 6.

A reflection ring 68 is mounted on the upper portion of the inner wall surface of the chamber side portion 61, and a reflection ring 69 is mounted on the lower portion thereof. Both of the reflection rings 68 and 69 have an annular shape. The upper reflection ring 68 is mounted by being fitted from above the chamber side portion 61. On the other hand, the lower reflection ring 69 is mounted by being fitted from below the chamber side portion 61 and fastened with screws (not shown). In other words, the reflection rings 68 and 69 are both removably mounted on the chamber side portion 61. The inner space of the chamber 6, that is, the space surrounded by the upper chamber window 63, the lower chamber window 64, the chamber side portion 61, and the reflection rings 68 and 69 is defined as a heat treatment space 65.

By mounting the reflection rings 68 and 69 to the chamber side portion 61, a recessed portion 62 is formed in the inner wall surface of the chamber 6. In other words, the recessed portion 62 is surrounded by the central portion of the inner wall surface of the chamber side portion 61 on which the reflection rings 68 and 69 are not mounted, the lower end face of the reflection ring 68, and the upper end face of the reflection ring 69. The recessed portion 62 is formed in an annular shape in the horizontal direction in the inner wall surface of the chamber 6 so as to surround the holding part 7 for holding the semiconductor wafer W.

The chamber side portion 61 and the reflection rings 68 and 69 are each formed of a metal material (e.g., stainless steel) having excellent strength and excellent heat resistance. The inner circumferential surfaces of the reflection rings 68 and 69 are mirror-finished by electrolytic nickel plating.

The chamber side portion 61 has a transport opening (throat) 66 formed therein for transporting the semiconductor wafer W into and out of the chamber 6. The transport opening 66 is configured to be openable and closable by means of a gate valve 185. The transport opening 66 is communicatively connected to the outer circumferential surface of the recessed portion 62. Accordingly, when the transport opening 66 is opened by the gate valve 185, the semiconductor wafer W can be transported from the transport opening 66 through the recessed portion 62 into the heat treatment space 65 and can be transported out of the heat treatment space 65 through the recessed portion 62 and the transport opening 66. When the transport opening 66 is closed by the gate valve 185, the heat treatment space 65 in the chamber 6 becomes an enclosed space.

The inner wall of the chamber 6 has, in its upper portion, a gas supply port 81 for supplying a treatment gas (in the present embodiment, nitrogen gas (N₂)) into the heat treatment space 65. The gas supply port 81 is formed at a position above the recessed portion 62 and may be provided in the reflection ring 68. The gas supply port 81 is communicatively connected to a gas supply pipe 83 via a buffer space 82 formed in an annular shape inside the side wall of the chamber 6. The gas supply pipe 83 is connected to a gas supply source 85. A valve 84 is interposed in the path of the gas supply pipe 83. When the valve 84 is opened, the nitrogen gas is fed from the gas supply source 85 into the buffer space 82. The nitrogen gas flowing into the buffer space 82 spreads out in the buffer space 82, which has lower fluid resistance than that of the gas supply port 81, and is then supplied through the gas supply port 81 into the heat treatment space 65. Note that the treatment gas is not limited to nitrogen gas, and may be an inert gas such as argon (Ar) or helium (He) or a reactive gas such as oxygen (O₂), hydrogen (H₂), chlorine (Cl₂), hydrogen chloride (HCl), ozone (O₃), or ammonia (NH₃).

The inner wall of the chamber 6 also has, in its lower portion, a gas exhaust port 86 for exhausting the gas in the heat treatment space 65. The gas exhaust port 86 is formed at a position below the recessed portion 62 and may be provided in the reflection ring 69. The gas exhaust port 86 is communicatively connected to a gas exhaust pipe 88 via a buffer space 87 formed in an annular configuration inside the side wall of the chamber 6. The gas exhaust pipe 88 is connected to an exhaust part 190. A valve 89 is interposed in the path of the gas exhaust pipe 88. When the valve 89 is opened, the gas in the heat treatment space 65 is discharged from the gas exhaust port 86 through the buffer space 87 into the gas exhaust pipe 88. Note that a plurality of gas supply ports 81 and a plurality of gas exhaust ports 86 may be provided in the circumferential direction of the chamber 6, and they may be slit-shaped. The gas supply source 85 and the exhaust part 190 may be mechanisms provided in the heat treatment apparatus 1, or they may be utilities in a factory where the heat treatment apparatus 1 is installed.

Also, a gas exhaust pipe 191 for discharging the gas in the heat treatment space 65 is connected to one end of the transport opening 66. The gas exhaust pipe 191 is connected to the exhaust part 190 via a valve 192. By opening the valve 192, the gas in the chamber 6 is discharged through the transport opening 66.

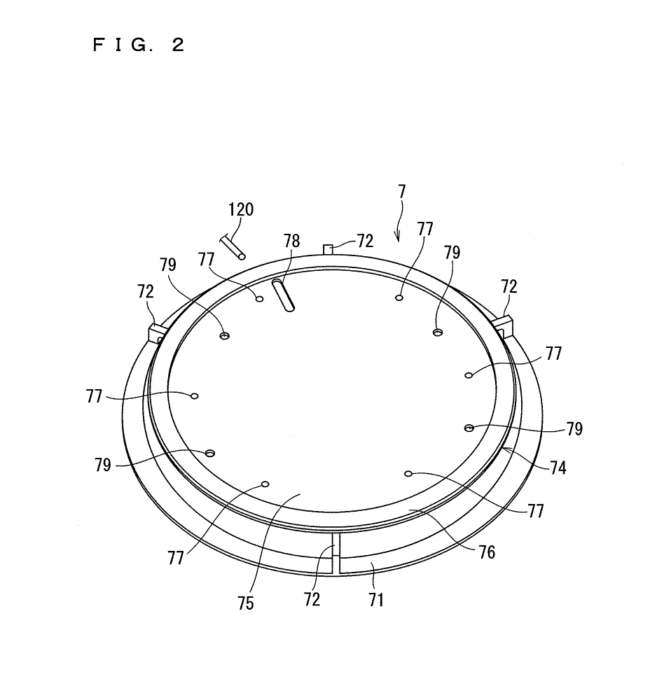

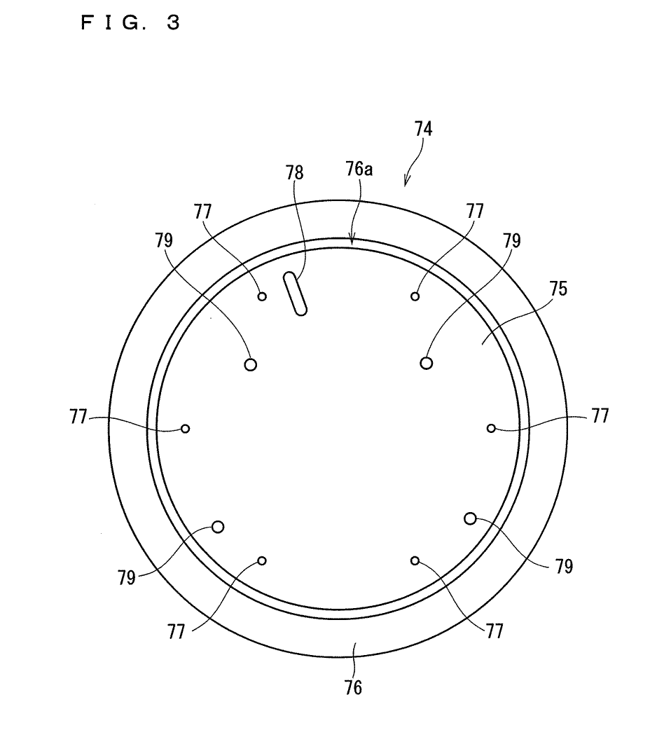

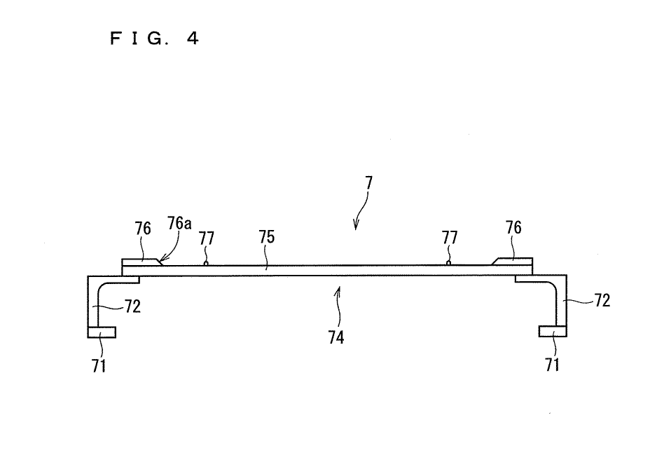

FIG. 2 is a perspective view showing an overall external view of the holding part 7. FIG. 3 is a plan view of a susceptor 74 of the holding part 7 as viewed from above. FIG. 4 is a side view of the holding part 7 as viewed from one side. The holding part 7 includes a base ring 71, connecting parts 72, and a susceptor 74. The base ring 71, the connecting parts 72, and the susceptor 74 are each made of quartz. In other words, the entire holding part 7 is made of quartz.

The base ring 71 is a quartz member having an annular shape. The base ring 71 is placed on the bottom face of the recessed portion 62 and thereby supported on the wall surface of the chamber 6 (see FIG. 1). On the top face of the base ring 71 having an annular shape, a plurality of (in the present embodiment, four) connecting parts 72 are provided upright in the circumferential direction of the base ring 71. The connecting parts 72 are also quartz members and are fixedly attached to the base ring 71 by welding. The base ring 71 may have an arc shape that is an annular shape with a missing part.

The susceptor 74 is supported by the four connecting parts 72 provided on the base ring 71. The susceptor 74 includes a holding plate 75, a guide ring 76, and a plurality of support pins 77. The holding plate 75 is a circular flat plate-like member made of quartz. The holding plate 75 has a diameter greater than that of the semiconductor wafer W. In other words, the holding plate 75 has a plane size greater than that of the semiconductor wafer W.

The guide ring 76 is installed on the peripheral portion of the top face of the holding plate 75. The guide ring 76 is an annular shaped member having an inside diameter greater than the diameter of the semiconductor wafer W. The guide ring 76 is made of the same quartz as that of the holding plate 75. The guide ring 76 may be welded to the top face of the holding plate 75, or may be fixed to the holding plate 75 with pins that are separately processed, for example. Alternatively, the guide ring 76 may be simply placed on the peripheral portion of the top face of the holding plate 75. When the guide ring 76 is welded to the holding plate 75, it is possible to inhibit the generation of particles due to sliding movement of the quartz members, whereas when the guide ring 76 is just placed on the holding plate 75, it is possible to prevent distortion of the holding plate 75 caused by welding.

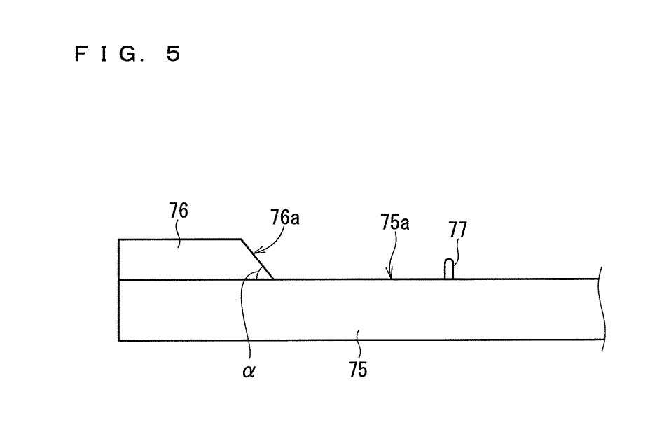

FIG. 5 is an enlarged view of a portion where the guide ring 76 is installed. The inner circumference of the guide ring 76 has a tapered surface 76a along the inner circumference, the tapered surface tapering from above down to the holding plate 75. Of the top face of the holding plate 75, a region that is located inwardly of an edge (lower edge) of the tapered surface 76a serves as a placement surface 75a on which the semiconductor wafer W is placed. The tapered surface 76a of the guide ring 76 has a gradient a of greater than or equal to 30 degrees and less than or equal to 70 degrees (in the present embodiment, 45 degrees) to the placement surface 75a of the holding plate 75. The tapered surface 76a has an average surface roughness (Ra) of less than or equal to 1.6 μm.

The guide ring 76 has an inside diameter (the diameter of a circle on the lower edge of the tapered surface 76a) that is 10 to 40 mm greater than the diameter of the semiconductor wafer W. Accordingly, when the semiconductor wafer W is held above the center of the placement surface 75a of the holding plate 75, the distance from the outer circumferential edge of the semiconductor wafer W to the edge of the tapered surface 76a is greater than or equal to 5 mm and less than or equal to 20 mm. In the present embodiment, the inside diameter of the guide ring 76 is 320 mm for a semiconductor wafer W having a diameter of 300 mm (the distance from the outer circumferential edge of the semiconductor wafer W to the edge of the tapered surface 76a is 10 mm). Note that the outside diameter of the guide ring 76 may be, but is not particularly limited to, for example, the same as the diameter of the holding plate 75 (in the present embodiment, 340 mm).

The support pins 77 are provided upright on the placement surface 75a of the holding plate 75. In the present embodiment, a total of six support pins 77 are provided upright every 60 degrees along the circumference of a circle concentric with the outer circumferential circle of the placement surface 75a (the inner circumferential circle of the guide ring 76). The diameter (the distance between opposed support pins 77) of the circle along which the six support pins 77 are disposed is smaller than the diameter of the semiconductor wafer W, and is 280 mm in the present embodiment. Each of the support pins 77 is made of quartz. The plurality of support pins 77 may be provided upright by being fitted to recessed portions formed in the top face of the holding plate 75.

The four connecting parts 72 provided upright on the base ring 71 and the peripheral portion of the underside of the holding plate 75 of the susceptor 74 are fixedly attached to each other by welding. In other words, the susceptor 74 and the base ring 71 are fixedly connected to each other by the connecting parts 72. This holding part 7 is attached to the chamber 6 by the base ring 71 of the holding part 7 being supported on the wall surface of the chamber 6. In a state in which the holding part 7 is attached to the chamber 6, the holding plate 75 of the susceptor 74 is in a horizontal position (a position at which the normal coincides with the vertical direction). The semiconductor wafer W transported into the chamber 6 is placed and held in the horizontal position on the susceptor 74 of the holding part 7 attached to the chamber 6. At this time, the semiconductor wafer W is supported in point contact by the plurality of support pins 77 provided upright on the holding plate 75, and is held by the susceptor 74. In other words, the semiconductor wafer W is supported by the plurality of support pins 77 with a predetermined gap from the placement surface 75a of the holding plate 75. In addition, the thickness of the guide ring 76 is greater than the height of the support pins 77. Thus, the guide ring 76 prevents the position of the semiconductor wafer W supported by the support pins 77 from being shifted in the horizontal direction.

As shown in FIGS. 2 and 3, the holding plate 75 of the susceptor 74 has formed therein a vertically penetrating opening 78. The opening 78 is provided for allowing a radiation thermometer 120 to receive radiation light (infrared light) radiated from the underside of the semiconductor wafer W held by the susceptor 74. More specifically, the radiation thermometer 120 receives, through the opening 78, the light radiated from the back face of the semiconductor wafer W held by the susceptor 74, and the temperature of the semiconductor wafer W is measured by a separately placed detector. The holding plate 75 of the susceptor 74 further has formed therein four through holes 79 through which lift pins 12 of a transfer mechanism 10, which will be described later, pass for transferring the semiconductor wafer W.

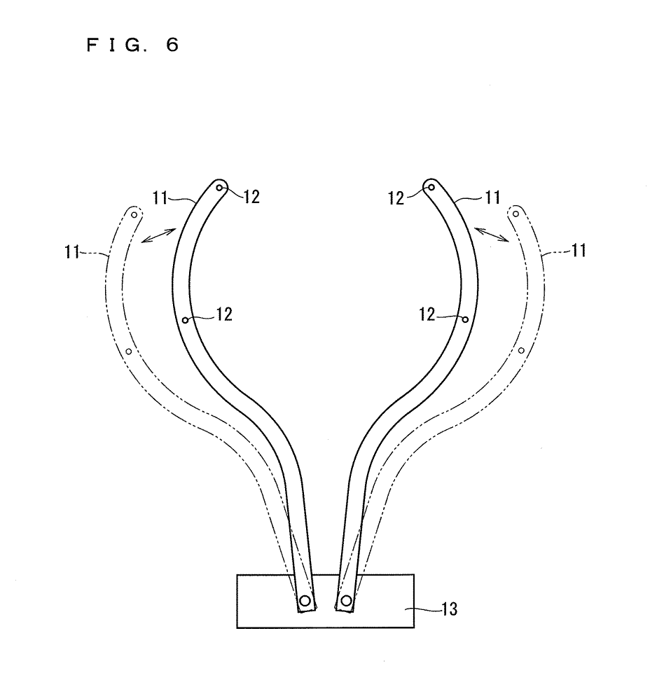

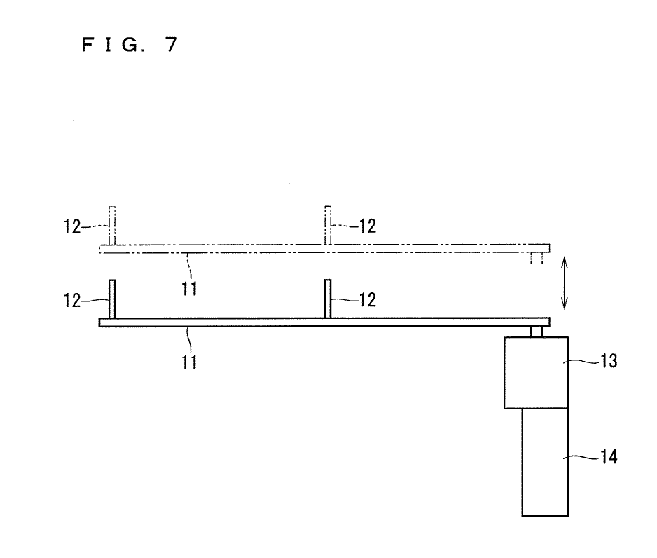

FIG. 6 is a plan view of the transfer mechanism 10. FIG. 7 is a side view of the transfer mechanism 10. The transfer mechanism 10 includes two transfer arms 11. The transfer arms 11 have an arc shape substantially along the annular recessed portion 62. The transfer arms 11 each have two lift pins 12 provided upright thereon. Each of the transfer arms 11 is configured to be pivotable by a horizontal movement mechanism 13. The horizontal movement mechanism 13 horizontally moves the pair of transfer arms 11 between a transfer operation position (the position indicated by the solid line in FIG. 6) at which the transfer of the semiconductor wafer W to the holding part 7 is performed and a retracted position (the position indicated by the dashed double-dotted line in FIG. 6) at which the transfer arms 11 do not overlap the semiconductor wafer W held on the holding part 7 in plan view. The horizontal movement mechanism 13 may be a mechanism for separately pivoting the transfer arms 11 by separate motors, or a mechanism for pivoting the pair of transfer arms 11 in conjunction with each other by a single motor using a link mechanism.

The pair of transfer arms 11 are also elevated and lowered together with the horizontal movement mechanism 13 by an elevating mechanism 14. When the elevating mechanism 14 elevates the pair of transfer arms 11 at the transfer operation position, the four lift pins 12 pass through the through holes 79 (see FIGS. 2 and 3) formed in the holding plate 75 of the susceptor 74 such that the upper ends of the lift pins 12 protrude from the top face of the holding plate 75. On the other hand, when the elevating mechanism 14 lowers the pair of transfer arms 11 at the transfer operation position to pull out the lift pins 12 from the through holes 79 and then the horizontal movement mechanism 13 moves the pair of transfer arms 11 to open the transfer arms 11, the transfer arms 11 move to the retracted position. The retracted position of the pair of transfer arms 11 is directly above the base ring 71 of the holding part 7. Because the base ring 71 is placed on the bottom face of the recessed portion 62, the retracted position of the transfer arms 11 is inside the recessed portion 62. Note that an exhaust mechanism (not shown) is also provided near the area where the driving parts (the horizontal movement mechanism 13 and the elevating mechanism 14) of the transfer mechanism 10 are provided so that the atmosphere around the driving parts of the transfer mechanism 10 is discharged to the outside of the chamber 6.

Referring back to FIG. 1, the flash heating part 5 provided above the chamber 6 includes, inside the casing 51, a light source composed of a plurality of (in the present embodiment, 30) xenon flash lamps FL and a reflector 52 provided so as to cover the top of the light source. Additionally, a lamp light radiation window 53 is attached to the bottom portion of the casing 51 of the flash heating part 5. The lamp light radiation window 53 constituting the floor portion of the flash heating part 5 is a plate-like quartz window made of quartz. Since the flash heating part 5 is installed above the chamber 6, the lamp light radiation window 53 is opposed to the upper chamber window 63. The flash lamps FL apply flash light to the heat treatment space 65 from above the chamber 6 through the lamp light radiation window 53 and the upper chamber window 63.

The flash lamps FL are each a rod-shaped lamp having an elongated cylindrical shape and are arranged in a planar array such that their longitudinal directions are parallel to each other along a main surface of the semiconductor wafer W held on the holding part 7 (i.e., in the horizontal direction). Thus, the plane formed by the array of the flash lamps FL is also a horizontal plane.

The xenon flash lamps FL each include a rod-shape glass tube (discharge tube) and a trigger electrode provided on the outer circumferential surface of the glass tube, the glass tube containing xenon gas sealed therein and including an anode and a cathode that are disposed at opposite ends of the glass tube and connected to a capacitor. Because xenon gas is an electrical insulating material, no electricity passes through the glass tube in a normal state even if electric charge is stored in the capacitor. However, if a high voltage is applied to the trigger electrode to cause an electrical breakdown, the electricity stored in the capacitor instantaneously flows through the glass tube, and xenon atoms or molecules are excited at this time to cause light emission. The xenon flash lamps FL have the properties of being capable of applying extremely intense light as compared with a continuously lit light source such as halogen lamps HL because the electrostatic energy previously stored in the capacitor is converted into an extremely short optical pulse of 0.1 to 100 milliseconds.

The reflector 52 is provided above the flash lamps FL so as to cover all of the flash lamps FL. A basic function of the reflector 52 is to reflect the flash light emitted from the flash lamps FL toward the heat treatment space 65. The reflector 52 is formed of a plate made of an aluminum alloy, and the surface (the surface facing the flash lamps FL) of the reflector 52 is roughened by blasting.

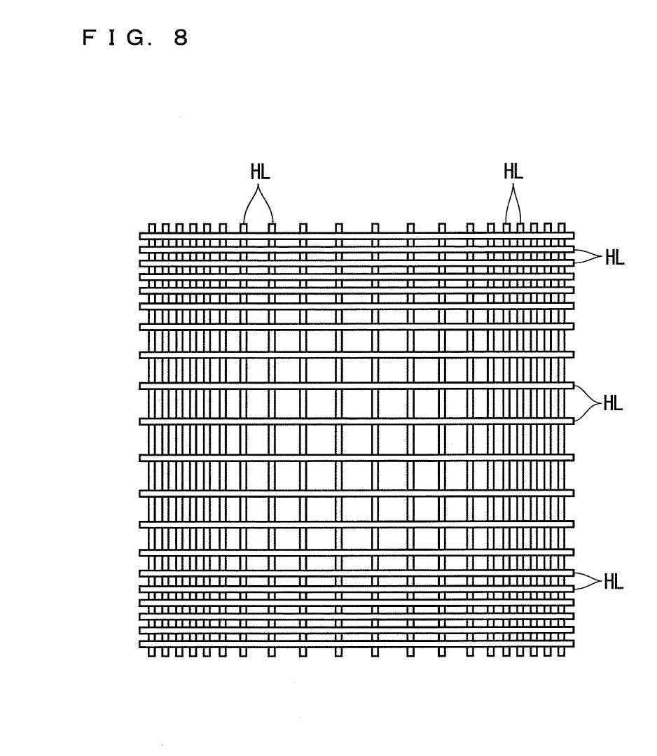

The halogen heating part 4 provided below the chamber 6 includes a plurality of (in the present embodiment, 40) halogen lamps HL. The halogen lamps HL apply light to the heat treatment space 65 from below the chamber 6 through the lower chamber window 64. FIG. 8 is a plan view showing the arrangement of the halogen lamps HL. In the present embodiment, 20 halogen lamps HL are arranged in an upper row, and 20 halogen lamps HL are arranged in a lower row. Each of the halogen lamps HL is a rod-shaped lamp having an elongated cylindrical shape. The 20 halogen lamps HL in the upper row are arranged such that their longitudinal directions are parallel to each other along the main surface of the semiconductor wafer W held on the holding part 7 (i.e., in the horizontal direction). The 20 halogen lamps HL in the lower row are arranged in the same manner. Thus, the plane formed by the array of the halogen lamps HL in the upper row and the plane formed by the array of the halogen lamps HL in the lower row are both horizontal planes.

As shown in FIG. 8, in each of the upper and lower rows, the halogen lamps HL are disposed at a higher density in a region opposed to the peripheral portion of the semiconductor wafer W held on the holding part 7 than in a region opposed to the central portion thereof. In other words, in each of the upper and lower rows, the halogen lamps HL are disposed at a shorter pitch in the peripheral portion of the array of the halogen lamps than in the central portion. This allows a larger amount of light to be applied to the peripheral portion of the semiconductor wafer W where the temperature tends to drop during heating by the application of light from the halogen heating part 4.

Also, a lamp group of the halogen lamps HL in the upper row and a lamp group of the halogen lamps HL in the lower rows are arranged so as to intersect in grids. In other words, a total of 40 halogen lamps are disposed such that the longitudinal direction of the halogen lamps HL in the upper row and the longitudinal direction of the halogen lamps HL in the lower row are orthogonal to each other.

The halogen lamps HL are each a filament-type light source that passes current through a filament disposed in the glass tube to make the filament incandescent, thereby emitting light. In the glass tube is sealed a gas prepared by introducing a halogen element (e.g., iodine or bromine) in trace amounts into an inert gas such as nitrogen or argon. The introduction of the halogen elements allows the temperature of the filament to be set at a high temperature while suppressing breakage of the filament. Thus, the halogen lamps HL have the properties of having a longer life than typical incandescent lamps and being capable of continuously applying intense light. The halogen lamps HL that are rod-shaped lamps have a long life, and disposing the halogen lamps HL in the horizontal direction enhances the radiation efficiently for the semiconductor wafer W located thereabove.

The controller 3 controls the above-described various operating mechanisms provided in the heat treatment apparatus 1. The controller 3 has a similar hardware configuration to that of a commonly used computer. More specifically, the controller 3 includes a CPU for executing various types of computation processing, a ROM, which is a read-only memory for storing a basic program, a RAM, which is a readable and writable memory for storing various pieces of information, and a magnetic disk for storing control software and data. The processing in the heat treatment apparatus 1 proceeds by the CPU of the controller 3 executing a predetermined processing program.

The heat treatment apparatus 1 includes, in addition to the above-described components, various cooling structures in order to prevent an excessive temperature increase in the halogen heating part 4, the flash heating part 5, and the chamber 6 due to heat energy generating from the halogen lamps HL and the flash lamps FL during the heat treatment of the semiconductor wafer W. For example, a water-cooled tube (not shown) is provided in the wall of the chamber 6. The halogen heating part 4 and the flash heating part 5 have an air cooling structure for forming a gas flow therein to exhaust heat. Air is also supplied to a gap between the upper chamber window 63 and the lamp light radiation window 53 to cool the flash heating part 5 and the upper chamber window 63.

Next is a description of a procedure for the treatment of the semiconductor wafer W in the heat treatment apparatus 1. The semiconductor wafer W to be treated here is a semiconductor substrate doped with impurities (ions) by ion implantation. The activation of the impurities is implemented by heat treatment (annealing) by the application of flash light performed by the heat treatment apparatus 1. The procedure for the treatment of the heat treatment apparatus 1 described below proceeds by the controller 3 controlling the operating mechanisms of the heat treatment apparatus 1.

First, the valve 84 for supplying gas is opened and the valves 89 and 192 for exhausting gas are opened, thereby starting gas supply and exhaust into and from the chamber 6. When the valve 84 is opened, nitrogen gas is supplied from the gas supply port 81 into the heat treatment space 65. When the valve 89 is opened, the gas in the chamber 6 is discharged from the gas exhaust port 86. Thereby, the nitrogen gas supplied from above the heat treatment space 65 within the chamber 6 flows downward and is discharged from below the heat treatment space 65.

As a result of the valve 192 being opened, the gas in the chamber 6 is discharged also from the transport opening 66. The atmosphere around the driving parts of the transfer mechanism 10 is also discharged from an exhaust mechanism (not shown). During the heat treatment of the semiconductor wafer W in the heat treatment apparatus 1, the nitrogen gas is continuously supplied into the heat treatment space 65, and the amount of the nitrogen gas supplied is changed as appropriate in accordance with the processing step.

Subsequently, the gate valve 185 is opened to open the transport opening 66, and the ion-implanted semiconductor wafer W is transported through the transport opening 66 into the heat treatment space 65 within the chamber 6 by a transport robot external to the heat treatment apparatus 1. The semiconductor wafer W transported into the heat treatment space 65 by the transport robot is stopped after moved to a position directly above the holding part 7. Then, the pair of transfer arms 11 of the transfer mechanism 10 are horizontally moved and elevated from the retracted position to the transfer operation position, and thereby the lift pins 12 protrude from the top face of the susceptor 74 through the through holes 79 to receive the semiconductor wafer W. At this time, the lift pins 12 are elevated above the upper end of the support pins 77 of the susceptor 74.

After placement of the semiconductor wafer W on the lift pins 12, the transport robot is withdrawn from the heat treatment space 65, and the gate valve 185 closes the transport opening 66. Then, the pair of transfer arms 11 is lowered so that the semiconductor wafer W is transferred from the transfer mechanism 10 to the susceptor 74 of the holding part 7 and held from below in the horizontal position by the susceptor 74.

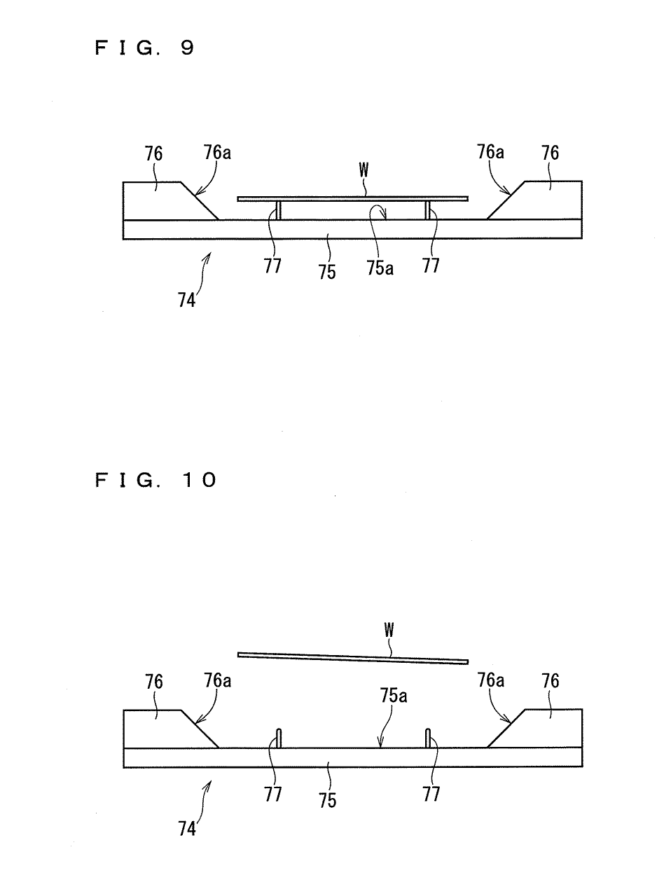

FIG. 9 shows a state in which the semiconductor wafer W is held by the susceptor 74. Note that FIGS. 9 to 12 are schematic diagrams in which the sizes of the guide ring 76 and the support pins 77 are exaggerated to facilitate the understanding. The semiconductor wafer W is supported in point contact by the support pins 77 provided upright on the holding plate 75 and is held by the susceptor 74. The semiconductor wafer W is supported by the support pins 77 such that the center thereof coincides with the central axis of the placement surface 75a of the holding plate 75 (i.e., at the center of the placement surface 75a). Thus, the semiconductor wafer W supported by the support pins 77 is at a fixed distance away from and inwardly of the tapered surface 76a along the inner circumference of the guide ring 76. Also, the semiconductor wafer W is held by the susceptor 74 with the surface thereof that has been patterned and implanted with impurities facing up. A predetermined gap is formed between the back face (the main surface opposite the front face) of the semiconductor wafer W supported by the support pins 77 and the placement surface 75a of the holding plate 75. The pair of transfer arms 11 that have been lowered below the susceptor 74 is retracted to the retracted position, or in other words, to the inside of the recessed portion 62, by the horizontal movement mechanism 13.

When the semiconductor wafer W is held from below in the horizontal position by the susceptor 74 of the holding part 7, the 40 halogen lamps HL of the halogen heating part 4 turn on all at once to start preheating (assist-heating). The halogen light emitted from the halogen lamps HL transmits through the lower chamber window 64 and the susceptor 74 made of quartz and is applied to the back face of the semiconductor wafer W. By receiving the light from the halogen lamps HL, the semiconductor wafer W is preheated and undergoes a temperature increase. Here, the transfer arms 11 of the transfer mechanism 10 will not impede the heating using the halogen lamps HL because they are retracted inside the recessed portion 62.

During the preheating using the halogen lamps HL, the temperature of the semiconductor wafer W is measured by the radiation thermometer 120. More specifically, the radiation thermometer 120 receives infrared light radiated through the opening 78 from the back face of the semiconductor wafer W held by the susceptor 74, and measures the wafer temperature during a rise in temperature. The measured temperature of the semiconductor wafer W is transmitted to the controller 3. The controller 3 monitors whether the temperature of the semiconductor wafer W that is increasing with the application of light from the halogen lamps HL has reached a predetermined preheating temperature T1. The preheating temperature T1 is set to about 200° C. to about 800° C. at which there is no possibility that the impurities doped in the semiconductor wafer W will be diffused by heat, and preferably, about 350° C. to about 600° C. (in the present embodiment, 600° C.).

After the temperature of the semiconductor wafer W has reached the preheating temperature T1, the controller 3 temporarily maintains the semiconductor wafer W at the preheating temperature T1. Specifically, at the point in time when the temperature of the semiconductor wafer W measured by the radiation thermometer 120 has reached the preheating temperature T1, the controller 3 controls the output of the halogen lamps HL to maintain the temperature of the semiconductor wafer W at approximately the preheating temperature T1.

Such preheating using the halogen lamps HL allows the entire semiconductor wafer W to be uniformly heated to the preheating temperature T1. In the preheating step using the halogen lamps HL, the temperature of the semiconductor wafer W tends to decrease more significantly in the peripheral portion where heat dissipation is more likely to occur than in the central portion. However, the halogen lamps HL of the halogen heating part 4 are disposed at a higher density in the region that is opposed to the peripheral portion of the semiconductor wafer W than in the region opposed to the central portion thereof. Accordingly, a greater amount of light is applied to the peripheral portion of the semiconductor wafer W where heat dissipation tends to occur, thereby making uniform the within-wafer temperature distribution of the semiconductor wafer W in the preheating step. Furthermore, the mirror-finished inner circumferential surface of the reflection ring 69 attached to the chamber side portion 61 increases the amount of light reflected by the inner circumferential surface of the reflection ring 69 toward the peripheral portion of the semiconductor wafer W, thereby making more uniform the within-wafer temperature distribution in the semiconductor wafer W in the preheating step.

At the point in time when a predetermined time has elapsed since the temperature of the semiconductor wafer W had reached the preheating temperature T1, the flash lamps FL of the flash heating part 5 apply flash light onto the surface of the semiconductor wafer W. At this time, part of the flash light radiated from the flash lamps FL travels directly into the chamber 6, whereas another part of the flash light is reflected by the reflector 52 and then travels into the chamber 6. The flash heating of the semiconductor wafer W is done by this application of flash light.

Because the flash heating is performed by the flash light applied from the flash lamps FL, the front face temperature of the semiconductor wafer W can be increased in a short time. More specifically, the flash light applied from the flash lamps FL is extremely short intense flash light that results from the conversion of the electrostatic energy previously stored in the capacitor into an extremely short optical pulse and whose irradiation time is about greater than or equal to 0.1 millisecond and about less than or equal to 100 milliseconds. The front face temperature of the semiconductor wafer W subjected to flash heating using the flash light applied from the flash lamps FL instantaneously rises to a treatment temperature T2 of greater than or equal to 1000° C., and then rapidly drops after activation of the impurities implanted in the semiconductor wafer W. Because of this capability of increasing and decreasing the front face temperature of the semiconductor wafer W in an extremely short time, the heat treatment apparatus 1 can activate the impurities while suppressing thermal diffusion of the impurities implanted in the semiconductor wafer W. Note that the time required for activation of impurities is extremely short as compared with the time required for thermal diffusion of impurities, and thus activation will be completed even in such a short time of about 0.1 to 100 milliseconds that causes no diffusion.

By this application of flash light, the front face temperature of the semiconductor wafer W instantaneously increases to the treatment temperature T2 of greater than or equal to 1000° C., whereas the back face temperature of the semiconductor wafer W does not increase so much from the preheating temperature T1. In other words, there is an instantaneous difference in temperature between the front and back faces of the semiconductor wafer W. As a result, abrupt thermal expansion occurs only in the front face of the semiconductor wafer W, whereas the back face hardly undergoes thermal expansion. The semiconductor wafer W thus suffers instantaneous warpage such that the front face thereof becomes raised. Such instantaneous warpage with the raised front face causes the semiconductor wafer W to jump off and be uplifted from the susceptor 74 as shown in FIG. 10.

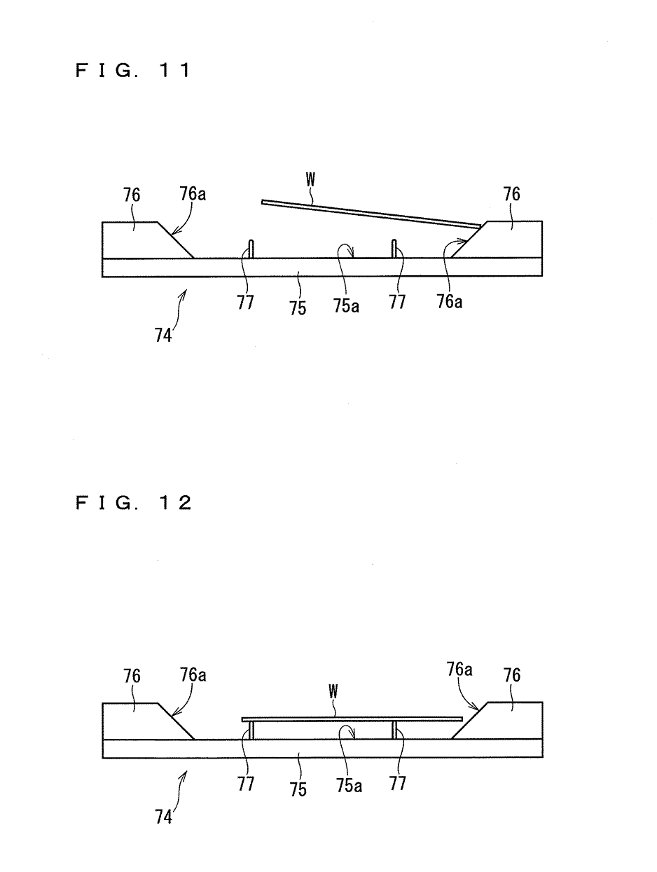

The semiconductor wafer W that has jumped off and been uplifted from the susceptor 74 falls toward the susceptor 74 immediately thereafter. At this time, the sheet semiconductor wafer W does not always jump upwardly in the vertical direction and fall directly in the vertical direction. Rather, the semiconductor wafer W often falls while being shifted in the horizontal direction. Consequently, the outer circumferential edge of the semiconductor wafer W may collide with the tapered surface 76a of the guide ring 76 as shown in FIG. 11.

The guide ring 76 is an annular shaped member, and the tapered surface 76a also has an annular shape. When the outer circumferential edge of the disc-shaped semiconductor wafer W collides with such an annular shaped member, the contact area at the time of the collision is larger than that when the semiconductor wafer W collides with conventional guide pins in point contact. Thus, the impact of the collision is reduced. As a result, it is possible to prevent cracks in the semiconductor wafer W when irradiated with flash light, and also to prevent damage to the guide ring 76.

In particular, when the outer circumferential edge of the semiconductor wafer W collides with the tapered surface 76a as shown in FIG. 11, kinetic energy is more dispersed than in the case where the outer circumferential edge of the semiconductor wafer W collides with a horizontal surface. This further reduces the impact of the collision and accordingly more reliably prevents cracks in the semiconductor wafer W.

Upon collision of the outer circumferential edge of the semiconductor wafer W with the tapered surface 76a, the outer circumferential edge slides obliquely downward along the tapered surface 76a, and thereby the position of the semiconductor wafer W in the horizontal direction is corrected to a position closer to the position before the application of flash light (the center of the placement surface 75a). Consequently, the fallen semiconductor wafer W is supported by the support pins 77 as shown in FIG. 12.

After a predetermined length of time has elapsed since the semiconductor wafer W jumped and fallen due to the application of flash light and was supported by the support pins 77, the halogen lamps HL turn off. This causes the temperature of the semiconductor wafer W to rapidly decrease from the preheating temperature T1. The dropping temperature of the semiconductor wafer W is also measured by the radiation thermometer 120, and the result of the measurement is transmitted to the controller 3. On the basis of the measurement result, the controller 3 monitors whether the temperature of the semiconductor wafer W has decreased to a predetermined temperature. After the temperature of the semiconductor wafer W has dropped to a predetermined temperature or below, the pair of transfer arms 11 of the transfer mechanism 10 are again horizontally moved and elevated from the retracted position to the transfer operation position, and thereby the lift pins 12 protrude from the top face of the susceptor 74 to receive the heat-treated semiconductor wafer W from the susceptor 74. Subsequently, the transport opening 66 that has been closed by the gate valve 185 is opened and the semiconductor wafer W placed on the lift pins 12 is transported out of the heat treatment apparatus 1 by the transport robot This completes the heat treatment of the semiconductor wafer W in the heat treatment apparatus 1.

As a result of the semiconductor wafer W having jumped and fallen when irradiated with flash light, the position of the semiconductor wafer W in the horizontal direction may be shifted from the position before the application of flash light. However, as shown in FIG. 12, if the semiconductor wafer W is supported by the support pins 77, it is possible to receive the semiconductor wafer W by the lift pins 12 of the transfer mechanism 10 and transport the semiconductor wafer W by the transport robot.

In the present embodiment, since the guide ring 76 has an annular shape, it is possible to increase the contact area when the semiconductor wafer W that has jumped and fallen when irradiated with flash light collides with the guide ring 76 and to thereby reduce the impact of the collision. Thus, it is possible to prevent cracks in the semiconductor wafer W resulting from the jumping and the subsequent falling of the semiconductor wafer W when irradiated with flash light.

In particular, the guide ring 76 has the tapered surface 76a along the inner circumference. Thus, it is possible, when the outer circumferential edge of the fallen semiconductor wafer W collides with the tapered surface 76a, to further reduce the impact of the collision and to more reliably prevent cracks in the semiconductor wafer W. When the outer circumferential edge of the fallen semiconductor wafer W collides with the tapered surface 76a, the semiconductor wafer W slides down along the slope of the tapered surface 76a, and thereby the position of the semiconductor wafer W in the horizontal direction that has been shifted as a result of the jumping and the subsequent falling is corrected to a position closer to the center of the placement surface 75a. This allows the fallen semiconductor wafer W to be supported by the support pins 77, then to be received by the lift pins 12, and to be transported by the transport robot.

Here, if the gradient a of the tapered surface 76a to the placement surface 75a of the holding plate 75 is greater than 70 degrees, it is difficult to achieve the effect of reducing the impact of collision when the jumped semiconductor wafer W has fallen and collided with the tapered surface 76a. On the other hand, if the gradient a of the tapered surface 76a to the placement surface 75a is smaller than 30 degrees, it is difficult to achieve the effect of correcting the position of the semiconductor wafer W when the semiconductor wafer W has fallen and collided with the tapered surface 76a, and on the contrary, the positional shift in the horizontal direction may increase. For this reason, the gradient a of the tapered surface 76a of the guide ring 76 to the placement surface 75a of the holding plate 75 is less than or equal to 30 degrees and greater than or equal to 70 degrees.

In the present embodiment, the tapered surface 76a has an average surface roughness of less than or equal to 1.6 Accordingly, when the outer circumferential edge of the fallen semiconductor wafer W collides with the tapered surface 76a, the outer circumferential edge can smoothly slide along the tapered surface 76a. Thus, it is possible to more reliably achieve the above position correction effect.

In the present embodiment, the guide ring 76 has an inside diameter that is 10 to 40 mm greater than the diameter of the semiconductor wafer W. If the difference is less than 10 mm, the semiconductor wafer W that has jumped when irradiated with flash light may fall outside the guide ring 76. On the other hand, if the difference is greater than 40 mm, the guide ring 76 will not only lose its inherent function of preventing the positional shift of the semiconductor wafer W in the horizontal direction but also have difficulty in achieving the above position correction effect. For this reason, the guide ring 76 has an inside diameter that is 10 to 40 mm greater than the diameter of the semiconductor wafer W.

While an embodiment of the present invention has been described above, various modifications of the present invention in addition to those described above may be made without departing from the scope and spirit of the invention. For example, although the guide ring 76 has the tapered surface 76a along the inner circumference in the above-described embodiment, the inner circumference of the guide ring 76 does not necessarily have to be a tapered surface. Even if the inner circumference of the guide ring 76 is not tapered, the contact area is large as long as the semiconductor wafer W that has jumped and fallen when irradiated with flash light collides with the annular shaped guide ring 76. Thus, it is still possible to reduce the impact of the collision and prevent cracks in the semiconductor wafer W. However, it is preferable for the guide ring 76 to have the tapered surface 76a along the inner circumference of as in the above-described embodiment, because not only the impact of collision can be further reduced, but also the position of the fallen semiconductor wafer W can be corrected to a position closer to the center of the placement surface 75a.

Although the susceptor 74 is made of quartz in the above-described embodiment, the present invention is not limited thereto. The susceptor 74 may be made of aluminum nitride (AlN) or silicon carbide (SiC). Alternatively, the holding plate 75 and the guide ring 76 may be made of different materials. For example, a guide ring 76 made of silicon carbide may be installed on the top face of a holding plate 75 made of quartz.

Although the flash heating part 5 includes the 30 flash lamps FL in the above-described embodiment, the present invention is not limited thereto. The flash heating part 5 may include an arbitrary number of flash lamps FL. The flash lamps FL are not limited to xenon flash lamps, and may be krypton flash lamps. The number of halogen lamps HL included in the halogen heating part 4 is also not limited to 40, and the halogen heating part 4 may include an arbitrary number of halogen lamps HL.

The substrates to be treated by the heat treatment apparatus according to the present invention are not limited to semiconductor wafers, and may be glass substrates for use in flat panel displays such as a liquid crystal display device, or substrates for use in solar cells. The technique according to the present invention is also applicable to bonding between metal and silicon or crystallization of polysilicon.

While the invention has been shown and described in detail, the foregoing description is in all aspects illustrative and not restrictive. It is therefore understood that numerous modifications and variations can be devised without departing from the scope of the invention.

What is claimed is:

1. A heat treatment method for heating a disc-shaped substrate by applying flash light to the substrate, the method comprising the steps of:
(a) applying flash light from a flash lamp to the substrate supported in point contact by a plurality of support pins provided upright on a holding plate; and
(b) causing an inner circumferential tapered surface of an annular shaped guide ring installed on the holding plate so as to surround the plurality of support pins to receive an outer circumferential edge of the substrate, when the substrate that has jumped off and been uplifted from the plurality of support pins falls due to the application of the flash light.

2. The heat treatment method according to claim 1, the method further comprising the step of:
(c) correcting a position of the substrate in the horizontal direction by
sliding down the substrate along the slope of the tapered surface, the substrate being received the outer circumferential edge by the tapered surface.

3. The heat treatment method according to claim 1, the method further comprising the step of:
(d) preheating the substrate supported by the plurality of support pins before said step (a).

4. The heat treatment method according to claim 1, wherein
the tapered surface has a gradient of greater than or equal to 30 degrees and less than or equal to 70 degrees to the plate.

5. The heat treatment method according to claim 1, wherein the tapered surface has an average surface roughness of less than or equal to 1.6 μm.

6. The heat treatment method according to claim 1, wherein the guide ring has an inside diameter that is 10 to 40 mm greater than the diameter of the substrate.
